(19) United States
(12) Patent Application Publication
(10) Pub. No.: US 2017/0207026 A1
(43) Pub. Date: Jul. 20, 2017

(54) ELECTRODE PATTERN FORMING METHOD AND ELECTRIC COMPONENT MANUFACTURING METHOD

(71) Applicant: MURATA MANUFACTURING CO., LTD., Kyoto-fu (JP)

(72) Inventors: Kunio IWAKOSHI, Nagaokakyo-shi (JP); Seiji GOTO, Nagaokakyo-shi (JP)

(73) Assignee: MURATA MANUFACTURING CO., LTD., Kyoto-fu (JP)

(21) Appl. No.: 15/395,059

(22) Filed: Dec. 30, 2016

(30) Foreign Application Priority Data
Jan. 19, 2016 (JP) 2016-007714

(51) Int. Cl. H01G 4/30; B32B 37/10; H01G 4/12; B32B 18/00; H05K 3/12; H01G 4/005

(52) U.S. Cl. CPC H01G 4/308; H05K 3/125; H01G 4/005; H01G 4/12; B32B 18/00; B32B 37/10; H05K 2203/013; B32B 2255/205; B32B 2307/202; B32B 2315/02; B32B 2457/08; B32B 2457/16

(57) ABSTRACT

An electrode pattern forming method capable of forming an electrode pattern having a desired thickness in each of a plurality of areas on an identical surface by an ink-jet method is provided. In a method of forming an electrode pattern including a first conductive portion and a second conductive portion connected with each other onto a work piece by an ink-jet method, a first area corresponding to at least part of the first conductive portion and a second area corresponding to at least part of the second conductive portion are defined on an identical surface of the work piece, conductive ink droplets are ejected toward the first area and the second area to form the first conductive portion and the second conductive portion, and a resolution of conductive ink droplets differs between the first area and the second area.

### CROSS REFERENCE TO RELATED APPLICATIONS

This application claims benefit of priority to Japanese Patent Application 2016-007714 filed Jan. 19, 2016, the entire content of which is incorporated herein by reference.

### TECHNICAL FIELD

The present disclosure relates to a method of forming an electrode pattern by an ink-jet method, and a method of manufacturing an electric component by using the electrode pattern.

### BACKGROUND

A conventional electrode pattern forming method is disclosed by, for example, Japanese Patent Laid-open No. 1996-222475. Japanese Patent Laid-open No. 1996-222475 discloses that a head provided to an ink-jet device sprays droplets of conductive ink to apply the conductive ink onto a principal surface of a work piece (for example, a ceramic green sheet, a resin film, or a mounting substrate) placed on a stage so as to form an internal electrode pattern on the principal surface of the work piece. In this case, the work piece is moved relative to the head in two directions (X direction and Y direction) orthogonal to each other in a substantially horizontal plane.

Japanese Patent Laid-open No. 1996-222475 further discloses a lamination process in which a work piece on which an internal electrode is formed is laminated and subjected to pressure bonding, a firing process that cuts and fires a laminated structure manufactured through the lamination process, and a forming process that forms a side electrode on a fired body manufactured through the firing process.

### SUMMARY

In the conventional electrode pattern forming method, conductive ink is sprayed at a fixed resolution. Thus, it has been difficult to form an electrode pattern having a desired thickness onto each of a plurality of areas on an identical surface.

Thus, the present disclosure is intended to provide an electrode pattern forming method capable of forming an electrode pattern having a desired thickness for each of a plurality of areas on an identical surface by an ink-jet method, and a method of manufacturing an electric component including the electrode pattern.

A first aspect of the present disclosure is a method of forming an electrode pattern including a first conductive portion and a second conductive portion connected with each other onto a work piece by an ink-jet method. A first area corresponding to at least part of the first conductive portion and a second area corresponding to at least part of the second conductive portion are defined on an identical surface of the work piece.

Conductive ink droplets are ejected toward the first area and the second area to form the first conductive portion and the second conductive portion. At least one of a resolution of conductive ink droplets and the number of iterations of recoating is different between the first area and the second area.

A second aspect of the present disclosure is a method of manufacturing an electric component, the method forming and firing a laminated structure including at least one work piece provided with the electrode pattern formed by the method according to the first aspect.

The above-described aspects can provide an electrode pattern forming method capable of forming an electrode pattern having a desired thickness for each of a plurality of areas in an identical surface by an ink-jet method, and a method of manufacturing an electric component including the electrode pattern.

### BRIEF DESCRIPTION OF THE DRAWINGS

FIG. 1 includes a front view and a top view of an ink-jet device.

FIG. 2 is a block diagram illustrating the configuration of a main part of the ink-jet device illustrated in FIG. 1.

FIG. 3 is a diagram illustrating resolutions in a first area and a second area on a work piece principal surface according to a first embodiment.

FIG. 4 is a diagram illustrating the configuration of bit map data according to a second embodiment.

FIG. 5 is a diagram illustrating a state transition of the first area and the second area on the work piece principal surface according to the second embodiment.

FIG. 6 is a diagram illustrating the configuration of bit map data according to a third embodiment.

FIG. 7 is a diagram illustrating a state transition of the first area and the second area on the work piece principal surface according to the third embodiment.

FIG. 8 is a diagram illustrating the configuration of bit map data according to a fourth embodiment.

FIG. 9 is a diagram illustrating a state transition of the first area and the second area on the work piece principal surface according to the fourth embodiment.

FIG. 10 is a diagram illustrating the first and second areas and a third area on the work piece principal surface according to a fifth embodiment.

FIG. 11 is a diagram illustrating the configuration of bit map data according to the fifth embodiment.

FIG. 12 is a diagram illustrating a state transition of the areas on the work piece principal surface according to the fifth embodiment.

FIG. 13 is a diagram illustrating a state transition when the third area is coated with conductive ink according to the fifth embodiment.

FIG. 14 is a diagram illustrating an electrode pattern according to an eighth embodiment.

FIG. 15 is a diagram illustrating an electrode pattern according to a ninth embodiment.

FIG. 16 is a diagram illustrating resolutions in the first area and the second area on the work piece principal surface according to the ninth embodiment.

### DETAILED DESCRIPTION

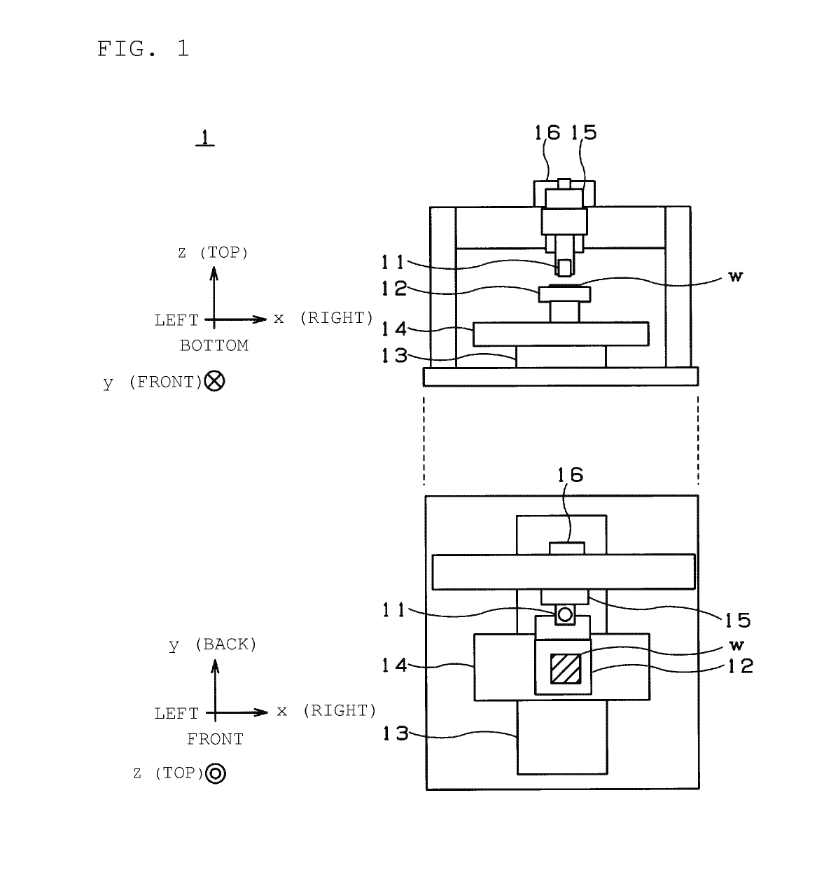

The following first describes an ink-jet device for forming an electrode pattern in detail with reference to FIG. 1.

### Definitions

First, arrows in each drawing will be described. In FIG. 1, arrows x, y, and z indicate a left-right direction, a front-back direction, and a top-bottom direction of an ink-jet device 1, respectively. The x direction and the y direction are also used to indicate a moving direction of a stage 12 provided to the ink-jet device 1. The xy plane is a horizontal plane.

Configuration and Operation of Ink-jet Device

In FIG. 1, the ink-jet device 1 includes a head 11, the stage 12, an x-axis directional movement mechanism 13, a y-axis directional movement mechanism 14, a z-axis directional movement mechanism 15, and a control unit 16.

The head 11 includes a plurality of nozzles arrayed in, for example, the x direction. Each of the nozzles ejects supplied conductive ink as an ink droplet by, for example, a piezoelectric scheme, a thermal scheme, or an electrostatic scheme. The ink droplet lands on a work piece and spreads to draw a substantially circular dot. In the ink-jet device 1, one or a plurality of the heads 11 may be arranged in line in, for example, the x direction, or may be arranged in a plurality of lines such that the array of the nozzles differs in the y direction to achieve an increased resolution.

An exemplary specification of a head is as follows.
Ink supply amount: between 1 pl and 40 pl inclusive
Head drive frequency: between 100 Hz and 50 kHz inclusive
The number of nozzles: between 100 and 2000 inclusive
Resolution: set to be between 180 dpi and 720 dpi inclusive

The dot drawn by the head 11 has a diameter, in other words, a dot diameter approximately between 5 μm and 100 μm inclusive depending on an ejection condition.

The conductive ink is, for example, metal ink obtained by dispersing particles of a metal including nickel, silver, or copper in a solvent. An exemplary specification of the metal ink is as follows.
Particle size: between 10 nm and 500 nm inclusive
Viscosity: between 5 mPa·s and 50 mPa·s inclusive

The stage 12 includes a placement surface on which a strip-shaped or elongated work piece w is placed. In the present embodiment, the stage 12 is shaped in a table including a placement surface parallel to the xy plane. However, the present disclosure is not limited thereto, and the stage 12 may be shaped in a roll. Examples of the work piece w include a ceramic green sheet, a resin film, or a mounting substrate (bare board). The stage 12 is provided with a vacuum suction unit (not illustrated) configured to fix the work piece w to an upper surface of the stage 12 by sucking the work piece w from below. The stage 12 may be provided with a temperature adjusting unit configured to facilitate drying of the ink by heating the work piece w to a predetermined temperature, for example, between 30° C. and 95° C. inclusive.

The movement mechanisms 13 to 15 relatively move the head 11 and the stage 12. In the present embodiment, the movement mechanism 13 moves the stage 12 in the left-right direction, and the movement mechanism 14 moves the stage 12 in the front-back direction. The movement mechanism 15 moves the head 11 in the top-bottom direction. When shaped in a roll, the stage 12 can be relatively moved through rotation.

In the ink-jet device 1, while the head 11 and the stage 12 are relatively moved, a plurality of dots are drawn on the work piece w through a plurality of times of ink ejection from the head 11 to the work piece w, thereby forming a pattern. A scanning operation refers to drawing of dots while relatively moving each of the head 11 and the stage 12 in one direction along, for example, the y direction orthogonal to the head 11 including the plurality of nozzles arrayed in the x direction. The relative movement in one direction is, for example, backward or forward movement without reversing in, for example, the y direction. The formation of the pattern is performed through a single scanning operation on the work piece w or through a plurality of times of scanning operations on the same region of the work piece w. Recoating refers to formation of a pattern through a scanning operation over a pattern formed through the previous scanning operation, in particular, by performing a plurality of times of scanning operations on the same region.

In a scanning operation, the direction in which the nozzles of the head 11 are arrayed does not need to be completely orthogonal to the direction in which the head 11 and the stage 12 are relatively moved, but these directions may be oblique to each other to some extent. When the pattern is formed through a plurality of times of scanning operations, ink droplets may be ejected under the same condition through all scanning operations or under different conditions between the scanning operations. In addition, the same head may be used through a plurality of times of scanning operations, or a plurality of heads or a plurality of ink-jet devices may be prepared and used for the respective scanning operations.

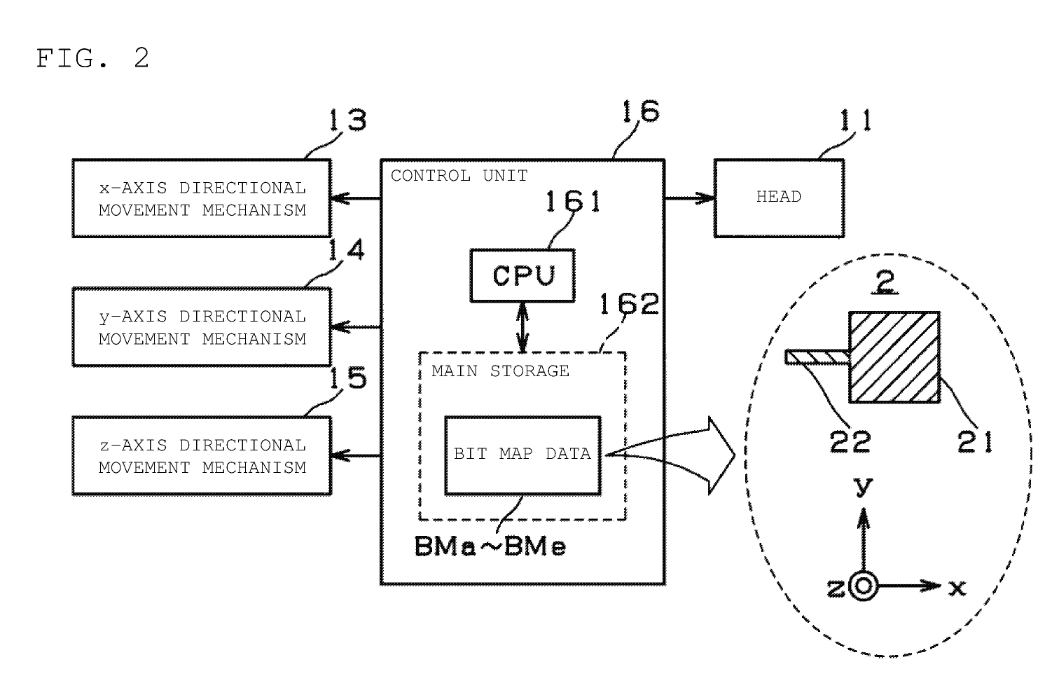

As illustrated in FIG. 2, the control unit 16 includes at least a CPU 161 and a main storage 162 to control each component of the ink-jet device 1. Specifically, the main storage 162 stores therein bit map data BMa. The bit map data BMa represents the shape, on the xy plane (which is a two-dimensional shape), of an electrode pattern 2 to be printed on a principal surface of the work piece w. The electrode pattern 2 includes a first conductive portion 21 and a second conductive portion 22 connected with the first conductive portion 21. The CPU 161 controls the relative movement of the head 11 and the stage 12 and the ejection of a conductive ink droplet onto the work piece w in accordance with the bit map data BMa stored in the main storage 162 so as to form, by printing, an electrode pattern on the principal surface of the work piece w. The speed of the printing is, for example, between 10 mm/s and 1000 mm/s inclusive.

### First Embodiment

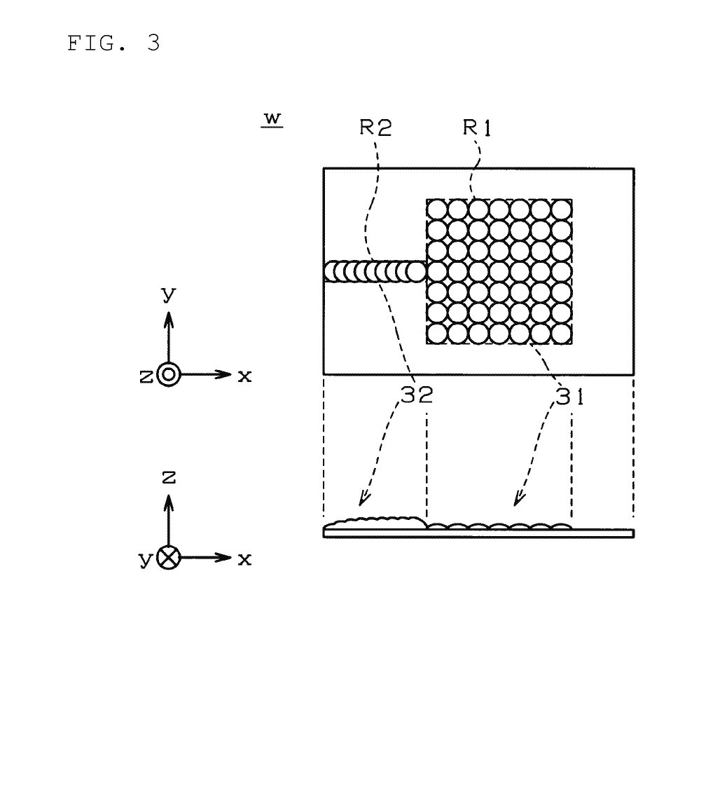

The following describes an electrode pattern forming method according to a first embodiment with reference to FIGS. 2 and 3. In the present embodiment, as illustrated in FIG. 2, the electrode pattern 2 includes a solid portion as the first conductive portion 21 and includes, as the second conductive portion 22, a line portion connected with the solid portion. The solid portion has a relatively large size in the x and y directions. The line portion has, in at least one of the x and y directions (which is a width direction), a size smaller than the size of the solid portion in any of the x and y directions. The solid portion is, for example, a rectangular capacitor electrode (which is one of opposite electrodes) in a ceramic capacitor, and the line portion is, for example, a wiring conductor connected with the capacitor electrode.

The conventional ink-jet device receives setting of a fixed resolution (the reciprocal of the resolution is referred to as a drop-landing interval) before the formation of the electrode pattern 2. The conventional ink-jet device ejects conductive ink droplets toward the work piece at a constant interval in accordance with the set resolution. In this case, the line portion and the solid portion are expected to have thicknesses equivalent to each other. However, when the thickness of the line portion is reduced to be small, no overlapping of conductive ink droplets is provided in the width direction, or the overlapping is smaller than in the length direction. Accordingly, the line portion receives a smaller number of droplets per unit area on the work piece than the solid portion, and as a result, the thickness of the line portion becomes smaller than that of the solid portion.

In an ink-jet method, the viscosity of conductive ink droplets is set to be small as appropriate to achieve excellent ejection performance of the droplets. Thus, the conductive ink on the work piece is likely to flow right after ejection. In addition, the conductive ink in the line portion tends to be moved toward the solid portion due to the effect of surface tension.

As described above, in the conventional ink-jet device, when the electrode pattern 2 including the line portion and the solid portion connected with each other is formed, the solid portion tends to be thick and the line portion tends to be thin. For example, when a work piece on which such an electrode pattern 2 is formed is laminated and fired, a structural defect is likely to occur in the solid portion, and a failure such as breaking, reduction of a current resistant property, or degradation of a high frequency characteristic is likely to occur in the line portion. In the work piece on which such an electrode pattern 2 is formed, a failure such as breaking, reduction of the current resistant property, or degradation of the high frequency characteristic is likely to occur in the line portion. For example, when a laminated structure of a work piece on which such an electrode pattern 2 is formed and fired, a structural defect is likely to occur in the solid portion.

In the present embodiment, as illustrated in FIG. 3, on an identical principal surface of the work piece w, a first area 31 is defined to be an area in which the first conductive portion (solid portion) is to be formed, and a second area 32 is defined to be an area in which the second conductive portion 22 (line portion) is to be formed. A resolution R2 of conductive ink droplets ejected onto the second area 32 is set to be higher than a resolution R1 of conductive ink droplets ejected onto the first area 31. The bit map data BMa according to the present embodiment includes at least data on the two-dimensional shapes of the areas 31 and 32 and the resolutions R1 and R2 of the areas 31 and 32. The resolutions R1 and R2 are preferably selected to be between 20% and 70% inclusive of the dot diameter as appropriate so that adjacent conductive ink droplets overlap with each other. FIG. 3 exemplarily illustrates the electrode pattern in which the resolution R2 is about twice as large as the resolution R1. In accordance with the bit map data BMa as described above, the CPU 161 operates the ink-jet device 1 to form the electrode pattern 2 on the principal surface of the work piece w. Specifically, in one scanning operation, an area having a low resolution is formed through an operation with, for example, a reduced number of nozzles used for the ink ejection among the nozzles of the head 11 or a longer time interval in which the ejection is performed as compared to formation of an area having a high resolution. When heads are arranged in a plurality of lines, an area having a low resolution may be formed with a reduced number of lines used for the ink ejection among the plurality of lines of heads as compared to formation of an area having a high resolution. Among two separate scanning operations or more, a scanning operation to form a pattern having a high resolution and a scanning operation to form a pattern having a low resolution may be performed by, for example, a method that employs different conditions of the ink droplet ejection. However, different resolutions can be employed within one scanning operation only by configuring the bit map data without managing a plurality of ejection conditions, which leads to easy management and high productivity.

### Effect of First Embodiment

After the electrode pattern 2 is formed, the electrode pattern 2 starts drying at a temperature of 250° C. or lower. Since the conductive ink still has flowability right after the formation of the electrode pattern 2, the conductive ink in the line portion tends to be moved toward the solid portion due to the effect of surface tension. However, as described above, the resolution R2 is higher than the resolution R1, and the degree of overlapping of conductive ink droplets is higher in the line portion than in the solid portion. As a result, the line portion is thicker than the solid portion. Thus, the line portion can be prevented from being extremely thin when the conductive ink in the line portion is moved toward the solid portion to some extent. Accordingly, for example, when the work piece w on which the electrode pattern 2 is formed is laminated and fired to manufacture an electric component, a structural defect is unlikely to occur in the solid portion, and a failure such as breaking, reduction of the current resistant property, or degradation of the high frequency characteristic is unlikely to occur in the line portion.

Upon completion of the drying process described above, the electrode pattern 2 including the conductive portions 21 and connected with each other is completely formed on the identical principal surface of the work piece w.

### Second Embodiment

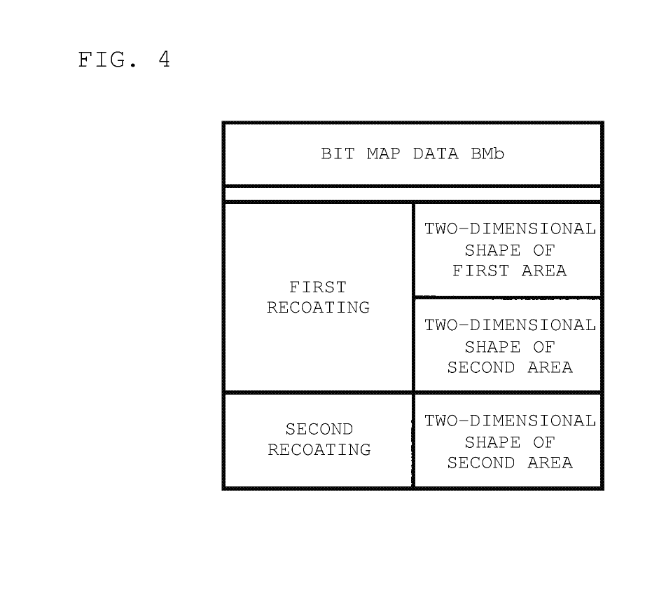

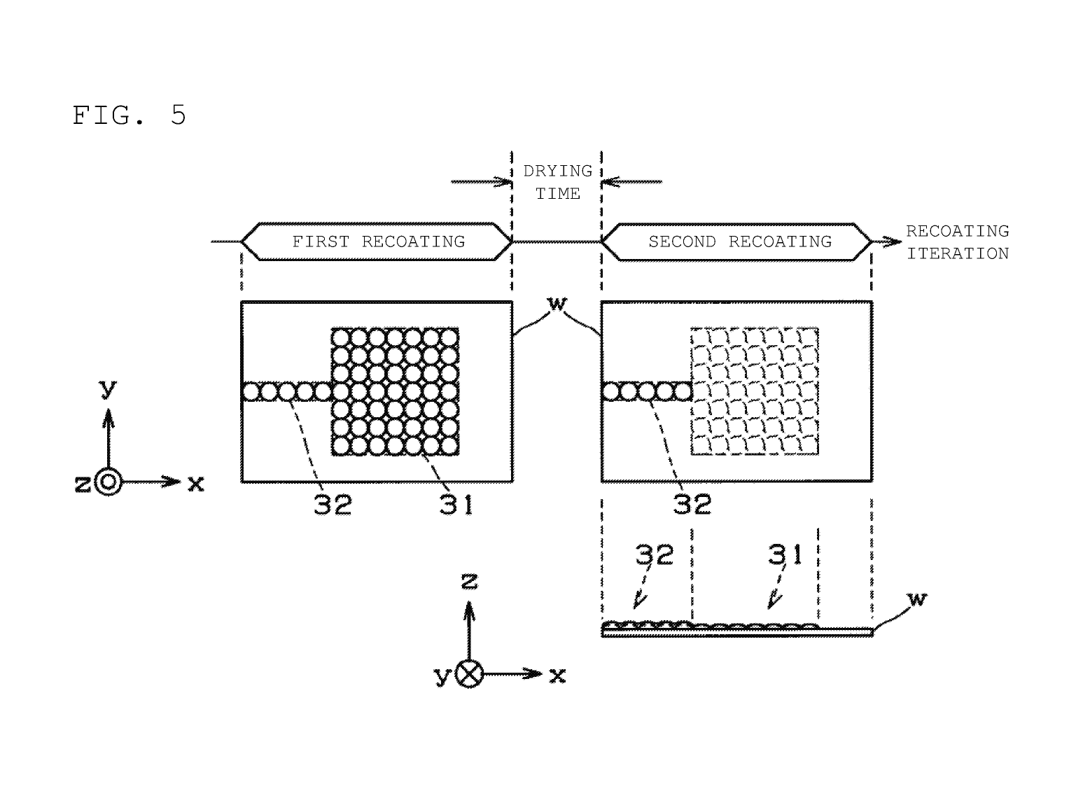

The following describes an electrode pattern forming method according to a second embodiment with reference to FIGS. 4 and 5 in addition to FIG. 2. The second embodiment is different from the first embodiment in that the electrode pattern 2 is formed by performing recoating through a plurality of times of scanning operations based on bit map data BMb different from the counterpart in the first embodiment. There is no other difference between the embodiments except for the above-described difference, and thus any component in the second embodiment corresponding to that in the first embodiment is denoted by an identical reference sign, and a description thereof will be omitted.

The bit map data BMa according to the first embodiment includes data on a pair of a two-dimensional shape and a resolution for each area. However, as illustrated in FIG. 4, the bit map data BMb according to the present embodiment includes at least data on the two-dimensional shape of an area to be coated at each iteration of recoating. The bit map data BMb is at least configured such that the second area 32 is coated a larger number of times than the first area 31. With the configuration illustrated in FIG. 4, the bit map data BMb indicates that the number of iterations of recoating is two, conductive ink droplets are ejected onto the areas 31 and 32 at the first time, and conductive ink droplets are ejected only onto the second area 32 at the second time. In the present embodiment, the areas 31 and 32 have resolutions identical to each other such that adjacent conductive ink droplets are in contact with each other. Alternatively, the order of recoating may be changed such that conductive ink droplets are ejected only onto the second area 32 at the first time, and conductive ink droplets are ejected to the areas 31 and 32 at the second time. The ejection may be performed under different ejection conditions between the first time and the second time.

### Effect of Second Embodiment

In the present embodiment, the CPU 161 forms the electrode pattern 2 on the identical principal surface of the work piece w in accordance with the bit map data BMb. Specifically, as illustrated in an upper part of FIG. 5, conductive ink droplets are ejected toward the areas 31 and 32 at the first coating, and conductive ink droplets are ejected only onto the second area 32 at the second coating. In a right part of FIG. 5, conductive ink droplets at the first time are illustrated with thin dotted lines. A drying time of 0.1 s or longer is preferably provided between the n-th coating and the (n+1)-th coating, in other words, between scanning operations. As a result of such recoating, the line portion is thicker than the solid portion as illustrated in a lower part of FIG. 5, and thus the technological effect described in the first embodiment can be obtained also in the present embodiment.

After the recoating as described above, the conductive ink is dried, and as a result, the electrode pattern 2 including the conductive portions 21 and 22 connected with each other (refer to FIG. 2) is completely formed on the identical principal surface of the work piece w.

In the present embodiment, since the drying time is provided for each scanning operation as described above, conductive ink droplets on the work piece w are dried to some extent, thereby reducing bleeding of the conductive ink and/or flow of the conductive ink into the solid portion.

### Third Embodiment

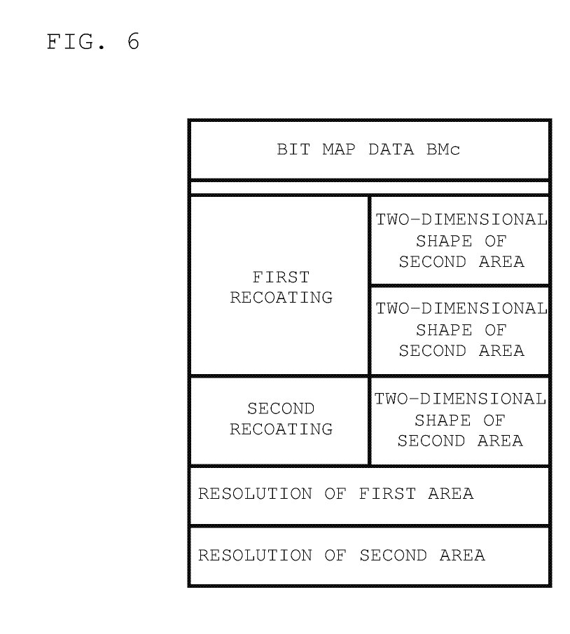

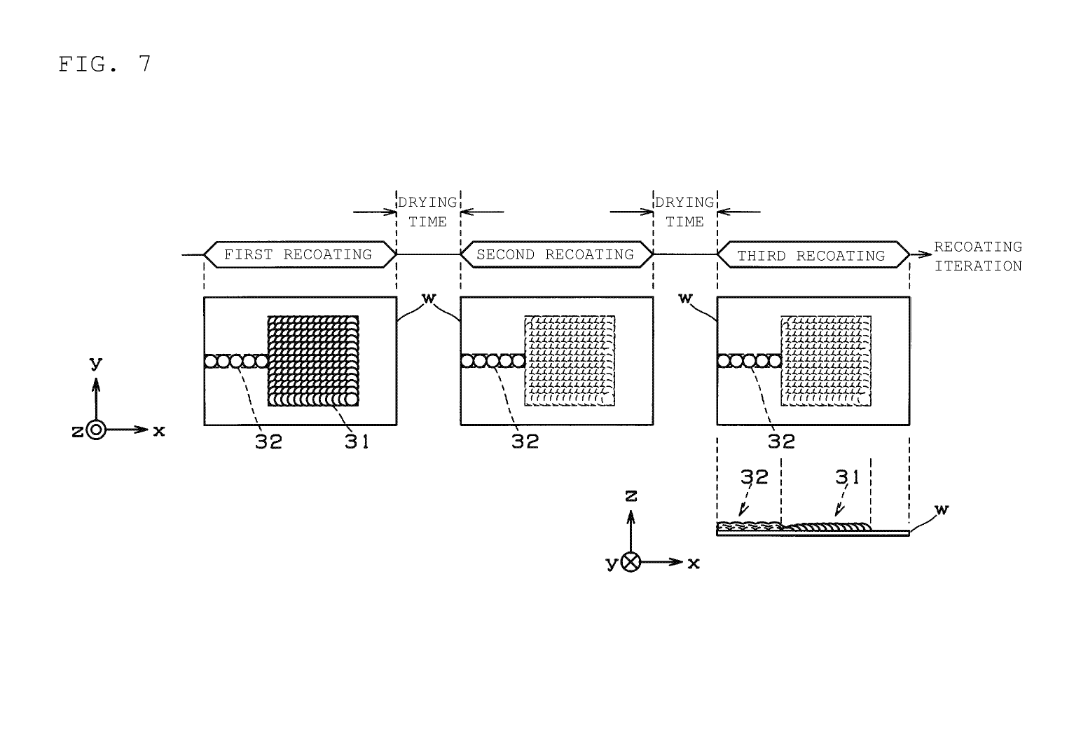

The following describes an electrode pattern forming method according to a third embodiment with reference to FIGS. 6 and 7 in addition to FIG. 2. The third embodiment is a combination of the first embodiment and the second embodiment. The third embodiment has no other difference from the first and second embodiments, and thus any component in the third embodiment corresponding to that in the first embodiment is denoted by an identical reference sign, and a description thereof will be omitted.

As illustrated in FIG. 6, bit map data BMc according to the third embodiment includes at least data on the two-dimensional shape of an area to be coated at each iteration of recoating, and data on the resolutions R1 and R2 of the areas 31 and 32. In the bit map data BMc, the resolutions R1 and R2 are set to values satisfying R1>R2, and the number of iterations of recoating and a two-dimensional shape to be coated at each iteration are set so that the thickness of conductive ink droplets is larger in the second area 32 than in the first area 31. The example illustrated in FIG. 6 indicates that the resolution R1 is about twice as large as the resolution R2, the number of iterations of recoating is three, and conductive ink droplets are ejected onto the areas 31 and 32 at the first time, but only onto the second area 32 at the second time and the third time.

### Effect of Third Embodiment

In the present embodiment, the CPU 161 forms the electrode pattern 2 onto an identical principal surface of the work piece w in accordance with the bit map data BMc. Specifically, as illustrated in an upper part of FIG. 7, at the first coating, conductive ink droplets are ejected onto the first area 31 at the resolution R1 and onto the second area 32 at the resolution R2 (R2<R1). At the second coating and the third coating, conductive ink droplets are ejected only onto the second area 32 at the resolution R2. In FIG. 5, conductive ink droplets ejected in the past are illustrated with thin dotted lines. In the present embodiment, the drying time described above is provided. As a result of such recoating, the line portion has a larger thickness than the solid portion as illustrated in a lower part of FIG. 7, and thus the technological effect described in the first embodiment can be obtained also in the present embodiment.

After the recoating as described above, the conductive ink is dried, and as a result, the electrode pattern 2 including the conductive portions 21 and 22 connected with each other (refer to FIG. 2) is completely formed on the identical principal surface of the work piece w.

Since the resolution R1 of the solid portion is large, the conductive ink is prompted to flow from the line portion to the solid portion, which is a unique effect of the present embodiment. As a result, the conductive ink can have an increased coverage in the first area 31.

### Fourth Embodiment

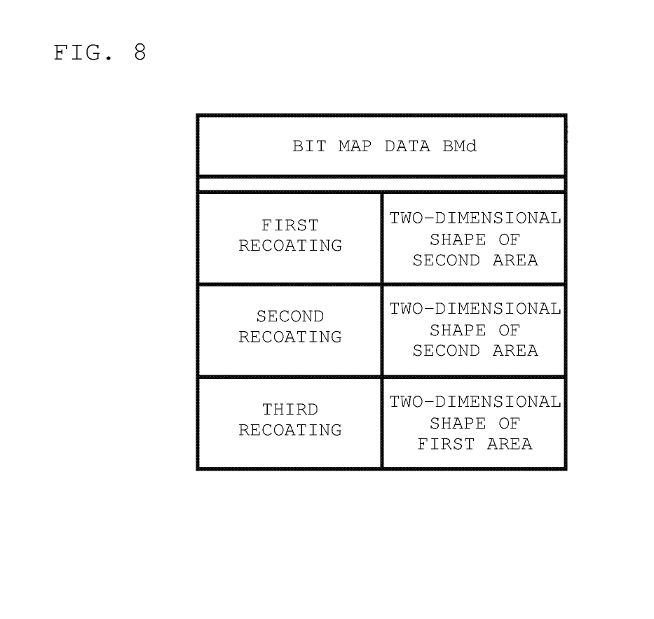

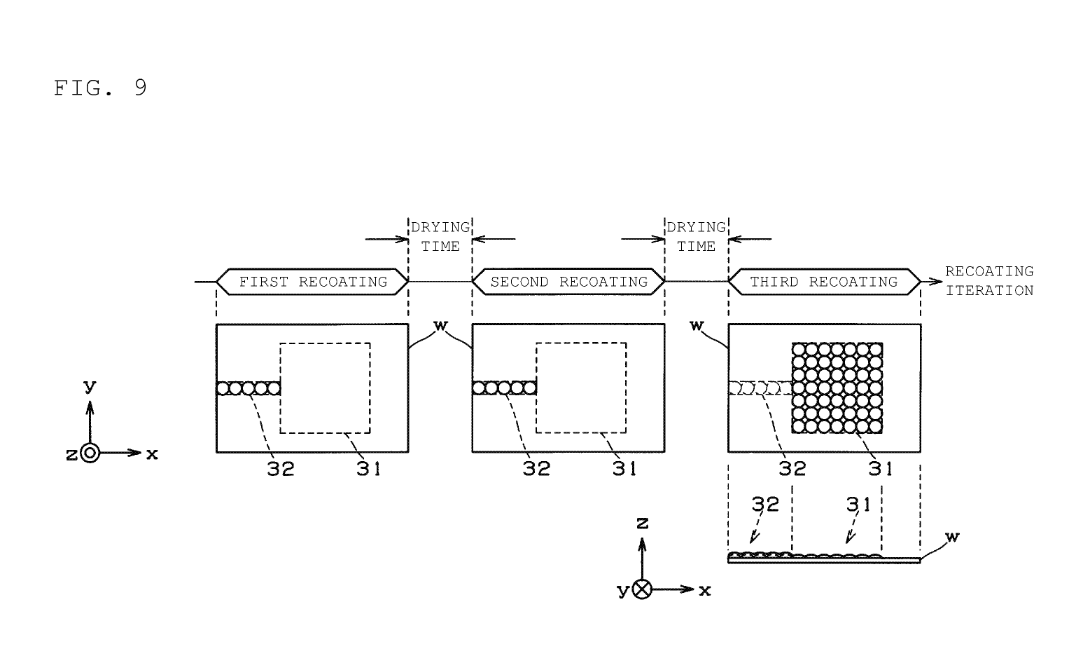

The following describes an electrode pattern forming method according to a fourth embodiment with reference to FIGS. 8 and 9 in addition to FIG. 2. The fourth embodiment differs from the second embodiment in that the electrode pattern 2 is formed through a plurality of iterations of recoating based on bit map data BMd different from the counterpart in the second embodiment. There is no other difference between the embodiments, and thus any component in the fourth embodiment corresponding to that in the second embodiment is denoted by an identical reference sign, and a description thereof will be omitted.

In comparison with the bit map data BMb, the bit map data BMd includes information indicating the two-dimensional shape of an area to be coated at each iteration of recoating as illustrated in FIG. 8. In the present embodiment, the bit map data BMd indicates that conductive ink droplets are ejected toward the second area 32 at the first two iterations of coating, but toward the first area 31 at the third coating.

### Effect of Fourth Embodiment

In the present embodiment, the CPU 161 forms the electrode pattern 2 onto an identical principal surface of the work piece w in accordance with the bit map data BMd. Specifically, as illustrated in FIG. 9, conductive ink droplets are ejected only toward the second area 32 at the first and second coating, but only toward the first area 31 at the third coating. In FIG. 9, conductive ink droplets ejected in the past are indicated with thin dotted lines. The drying time described above is preferably provided also in the present embodiment. As a result of such recoating, the line portion is dried faster, and thus the flow of the conductive ink from the line portion to the solid portion can be excellently reduced. Accordingly, the line portion is thicker than the solid portion as illustrated in a lower part of FIG. 9, and thus the technological effect described in the first embodiment can be obtained also in the present embodiment.

### Note of Fourth Embodiment

The same idea as that in the fourth embodiment (coat the second area 32 first) is applicable in any other embodiment.

### Fifth Embodiment

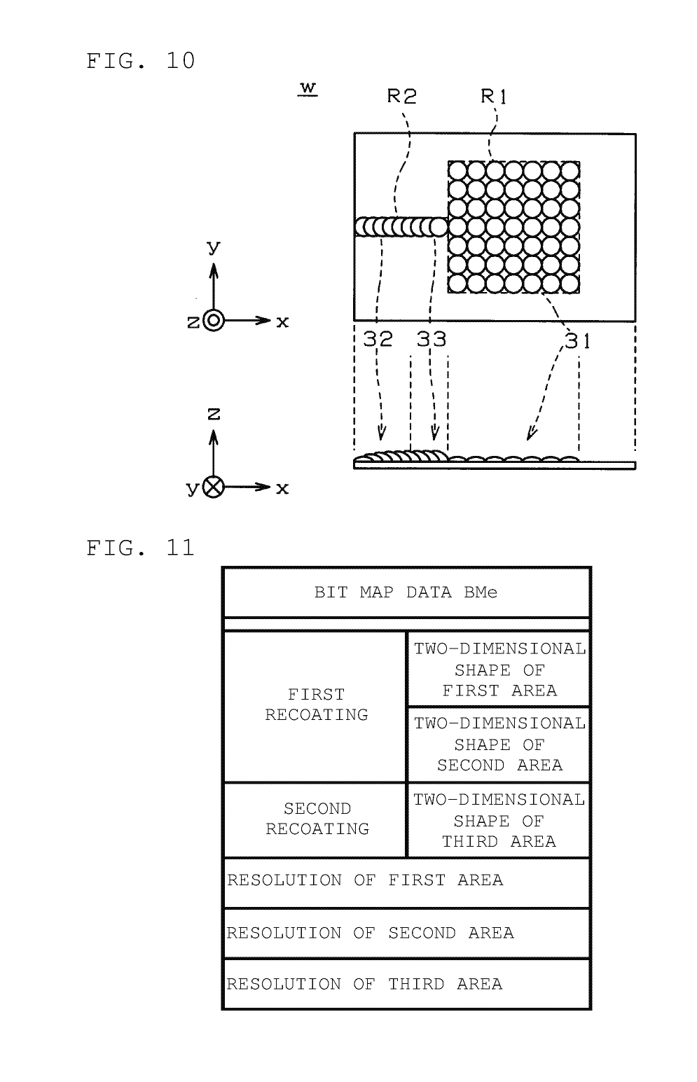

The following describes an electrode pattern forming method according to a fifth embodiment with reference to FIGS. 10 to 12 in addition to FIG. 2. In the present embodiment, too, the electrode pattern 2 includes the solid portion and the line portion connected with each other as illustrated in FIG. 2. As illustrated in FIG. 10, on an identical principal surface of the work piece w, the first area 31 is defined to be an area in which the solid portion is to be formed, and the second area 32 is defined to be an area in which the line portion is to be formed. A third area 33 is defined to be in the vicinity of a boundary between the solid portion and the line portion. In the present embodiment, the third area 33 is, for example, an area in the line portion, which is adjacent to the solid portion. However, the present disclosure is not limited thereto, and the third area 33 may be an area in the solid portion, which is adjacent to the line portion.

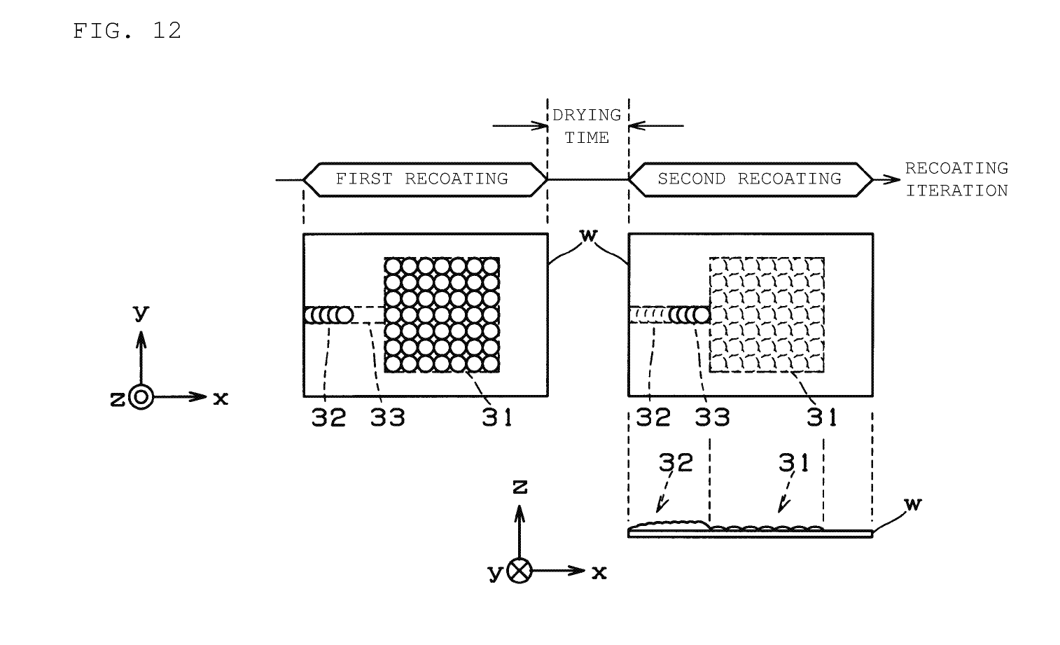

As illustrated in FIG. 11, bit map data BMe according to the present embodiment includes at least information indicating the two-dimensional shape of an area to be coated at each iteration of recoating, and resolutions of the areas 31, 32, and 33. In the present embodiment, the resolution R2 of conductive ink droplets ejected onto the areas 32 and 33 is set to be higher than the resolution R1 of conductive ink droplets ejected onto the first area 31. Refer to the first embodiment for the details of the resolutions R1 and R2.

### Effect of Fifth Embodiment

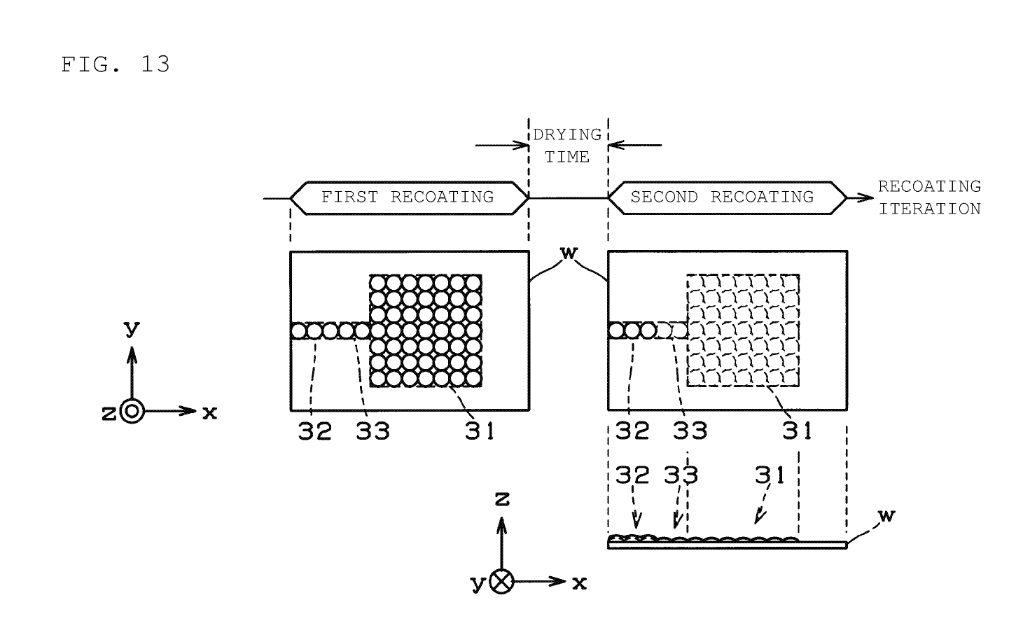

In the present embodiment, the CPU 161 forms the electrode pattern 2 onto an identical principal surface of the work piece w in accordance with the bit map data BMe described above. Specifically, as illustrated in an upper part of FIG. 12, conductive ink droplets are ejected onto the areas 31 and 32 at the resolutions R1 and R2 at the first coating. At the second coating, conductive ink droplets are ejected only onto the third area 33 at the resolution R2. In an upper part of FIG. 12, conductive ink droplets ejected in the past are indicated with thin dotted lines. The drying time described above is preferably provided also in the present embodiment.

In such recoating, the line portion and the solid portion are not connected at the first coating, and thus the conductive ink can be prevented from flowing from the line portion to the solid portion. Then, both parts are connected with each other at the second coating. In the present embodiment, the line portion has a resolution higher than that in the solid portion, and thus the line portion has a thickness larger than that in the solid portion as illustrated in a lower part of FIG. 12. In this manner, the technological effect described in the first embodiment can be obtained also in the present embodiment.

### Note of Fifth Embodiment

The third area 33 according to the present embodiment is applicable in any of the first to fourth embodiments.

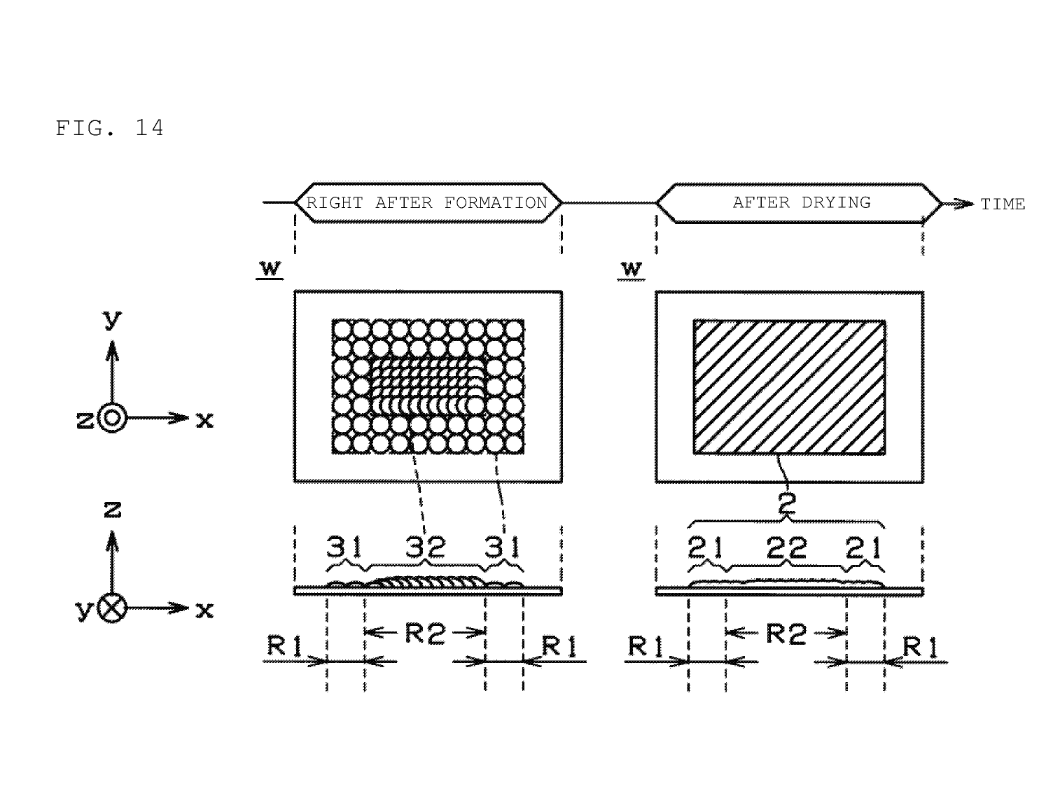

In the fifth embodiment described above, the resolution of the conductive ink and the number of iterations of recoating are constant for the third area 33. However, the present disclosure is not limited thereto, and the bit map data BMe may be defined appropriately so that the number of iterations of coating of conductive ink droplets in the third area 33 decreases at stages from the second area 32 toward the first area 31 as illustrated in FIG. 13. In addition, the resolution of conductive ink droplets in the third area 33 may be to decrease at stages from the second area 32 toward the first area 31.

When the line portion 22 includes a plurality of conductive ink droplets in the width direction, the width of the third area 33 in the front-back direction may be set to decrease at stages from the second area 32 toward the first area 31.

As described above, the thickness is set to gradually change between the line portion and the solid portion by setting the resolution, the number of iterations of recoating, or the width of the third area 33, thereby further reducing the flow of the conductive ink from the second area 32 to the first area 31.

### Sixth Embodiment

The following describes a method of manufacturing an electric component using the electrode pattern forming method according to each of the first to fifth embodiments. The electric component is, for example, a laminated ceramic electric component.

First, deposition and drying of a ceramic green sheet are performed as a first process. The deposition is performed by using a device such as a die coater, a doctor blade, a roll coater, or an ink-jet coater as appropriate. This deposition device forms a ceramic sheet by applying ceramic slurry onto a support body. The ceramic slurry is obtained by dissolving and dispersing, into an organic solvent (or an aqueous solvent), ceramic powder to which a resin component is added. The support body may be, for example, an elongated or strip-shaped resin film, metal roll, metal drum, metal belt, or metal plate.

In the first process, the ceramic sheet formed by the deposition device is dried by a drying device. More specifically, the drying device dries the ceramic sheet by a method through, for example, heated air, heating of the support body, or vacuum dry to obtain a ceramic green sheet. The drying may be performed by any method suitable for the property of the solvent.

In a subsequent second process, a ceramic green sheet on which a predetermined internal electrode pattern is formed is manufactured by the methods according to the first to fifth embodiments.

In a subsequent third process, first, a predetermined number of the ceramic green sheets on each of which the internal electrode pattern is formed are laminated on a support plate, and then subjected to pressure bonding. In this manner, a ceramic laminated structure is manufactured. The lamination and pressure bonding processes may be performed by using a typical laminator or devices disclosed by Japanese Patent Laid-open No. 2005-217278 and Japanese Patent Laid-open No. 2011-258928. The lamination and pressure bonding processes may be performed before or after separation from the support body.

The ceramic laminated structure manufactured through the lamination and pressure bonding processes is pressed by pressurization, and then cut into a desired size. Thereafter, a laminated ceramic electric component is completely formed through a firing process of firing at a temperature, for example, between 800° C. and 1200° C. and a process of forming an external electrode.

The laminated structure includes at least one work piece on which a predetermined electrode pattern is formed by the methods according to the first to fifth embodiments. Another method of forming a laminated structure repeats a process in which ink or paste including a work piece base material such as ceramic particle is prepared, a first work piece base material layer is formed onto a support body by a printing method such as the ink-jet method or a screen printing method, and then a first electrode pattern is formed on the work piece base material layer, and in addition, a second work piece base material layer is formed through printing of the ink or paste including the work piece base material onto the first work piece base material layer on which the first electrode pattern is formed, and a second electrode pattern on the second work piece base material layer is formed. In this case, too, the effect of the present disclosure can be obtained by forming a predetermined electrode pattern onto at least one work piece base material layer by the methods according to the first to fifth embodiments.

### Effect of Sixth Embodiment

Typically, in the process of firing a ceramic electric component, the electrode pattern 2 contracts more than ceramic. Thus, when the solid portion having a large area is thick, the amount of contraction largely differs across an interface between a ceramic part and the solid portion. As a result, structural defects such as cracking and delamination are likely to occur in the solid portion. When the line portion is thin, a failure such as breaking, reduction of the current resistant property, or degradation of the high frequency characteristic is likely to occur.

However, as described above, the electrode pattern 2 in which reduction in the thickness of the line portion can be prevented can be formed on the ceramic green sheet by the methods according to the first to fifth embodiments. In the sixth embodiment, the electric component is manufactured by using such a ceramic green sheet, and thus a structural defect is unlikely to occur in the solid portion, and a failure such as breaking, reduction of the current resistant property, or degradation of the high frequency characteristic is unlikely to occur in the line portion.

### Seventh Embodiment

In the process of manufacturing a ceramic electric component, a plurality of ceramic green sheets on each of which an internal electrode pattern is formed are laminated, and thus, in plan view along a lamination direction, an electrode pattern on a ceramic green sheet overlaps with an electrode pattern on another ceramic green sheet in some cases. If a large number of electrode patterns overlap with each other, a structural defect is potentially generated in the manufacturing process, or the flatness of a surface of a formed ceramic electric component is potentially affected.

In the present embodiment, in each electrode pattern 2 (refer to FIG. 2), the first conductive portion 21 is defined to be an area overlapping with another electrode pattern 2 in plan view along the lamination direction, and the second conductive portion 22 is defined to be the other area. The electrode pattern 2 including these conductive portions 21 and 22 may be formed onto the work piece w by the methods according to the first to fifth embodiments to avoid a structural defect in the manufacturing process and manufacture an electric component having a favorable flatness.

### Eighth Embodiment

When a solid electrode pattern is formed on the work piece w by the ink-jet method and dried, a peripheral portion of the electrode pattern 2 is likely to be thicker than an inner portion thereof due to the coffee stain phenomenon.

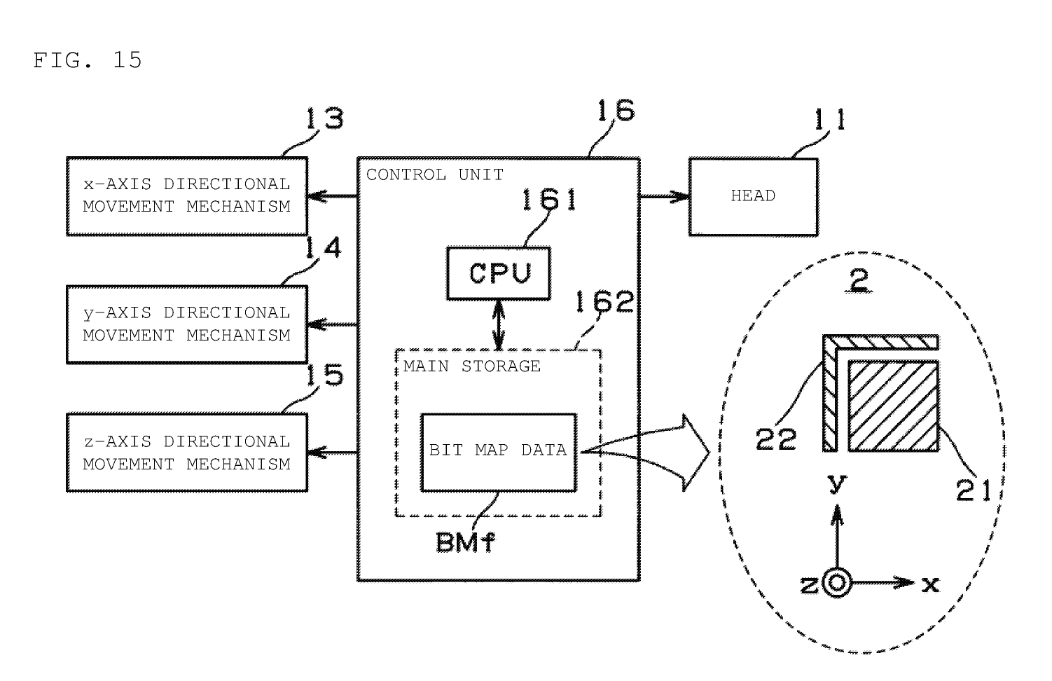

In the present embodiment, to achieve the flatness of the electrode pattern 2 described above, the peripheral portion assumed to be affected by the coffee stain phenomenon is designed to be thinner than the inner portion. In other words, the first conductive portion 21 is defined to be the peripheral portion of the electrode pattern 2, and the second conductive portion 22 is defined to be the inner portion. With these definitions, the electrode pattern 2 is formed on the work piece w by the methods according to the first to fifth embodiments. As a result, right after the electrode pattern 2 is formed on the work piece w, the thickness of the conductive ink is larger in the second area 32 (inner portion) than in the first area 31 (peripheral portion) as illustrated in a left part of FIG. 14.

However, after drying, the second conductive portion 22 (inner portion) has a thickness substantially the same as that of the first conductive portion 21 (peripheral portion) as illustrated in a right part of FIG. 14 due to the coffee stain phenomenon. Thus, flatness can be obtained in a large area of the electrode pattern 2.

### Ninth Embodiment

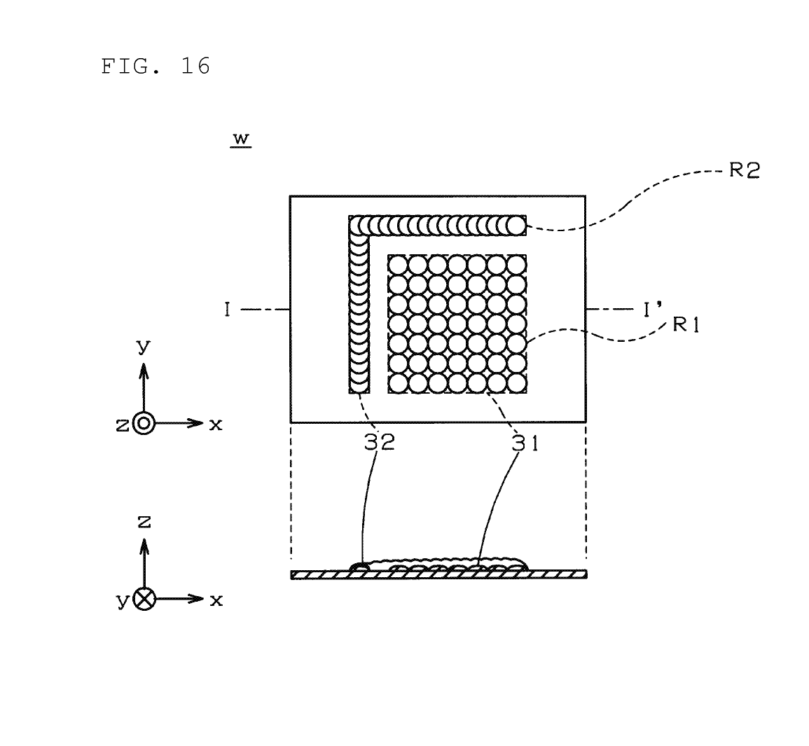

The following describes an electrode pattern forming method according to a ninth embodiment with reference to FIGS. 15 and 16. In the present embodiment, as illustrated in FIG. 15, the electrode pattern 2 includes a solid portion as the first conductive portion 21, and includes, as the second conductive portion 22, a line portion not connected with the solid portion. Refer to the first embodiment for the definitions of the solid portion and the line portion.

As described in the first embodiment, when the electrode pattern 2 as illustrated in FIG. 15 is formed by using the conventional ink-jet device, a fixed resolution is set, and thus the line portion has a thickness smaller than that of the solid portion. When a work piece on which such an electrode pattern 2 is formed is laminated and fired, a structural defect is likely to occur in the solid portion, and a failure such as breaking, reduction of the current resistant property, or degradation of the high frequency characteristic is likely to occur in the line portion. However, since the solid portion and the line portion are not connected with each other in the electrode pattern 2 illustrated in FIG. 15, the movement of the conductive ink toward the line portion to the solid portion due to the effect of surface tension does not occur.

In the present embodiment, as illustrated in FIG. 16, on an identical principal surface of the work piece w, the first area 31 is defined to be an area in which the first conductive portion 21 (solid portion) illustrated in FIG. 15 is to be formed, and the second area 32 is defined to be an area in which the second conductive portion 22 (line portion) is to be formed. A lower part of FIG. 16 illustrates a section taken along dashed and single-dotted line I-I′. The resolution R2 of conductive ink droplets in the second area 32 is set to be higher than the resolution R1 of conductive ink droplets ejected onto the first area 31. Bit map data BMf according to the present embodiment has a data structure the same as that of the bit map data BMa according to the first embodiment, and thus a detailed description thereof will be omitted.

### Effect of Ninth Embodiment

In the present embodiment, the CPU 161 forms the electrode pattern 2 on the principal surface of the work piece w in accordance with the bit map data BMf as described above. Thereafter, the electrode pattern 2 is dried. However, in the present embodiment, the line portion and the solid portion are not connected with each other, and the resolution R2 is higher than the resolution R1, and thus the line portion has a larger degree of overlapping of conductive ink droplets than the solid portion. As a result, the line portion is thicker than the solid portion. Accordingly, the line portion can be prevented from being thinner than the solid portion. Thus, for example, when the work piece w on which such an electrode pattern 2 is formed is laminated and fired to manufacture an electric component, a structural defect is unlikely to occur in the solid portion, and a failure such as breaking, reduction of the current resistant property, or degradation of the high frequency characteristic is unlikely to occur in the line portion.

### Tenth Embodiment

The following describes a method of manufacturing an electric component by using the electrode pattern forming method according to the ninth embodiment. The manufacturing method according to the present embodiment and an effect thereof differs from that of the seventh embodiment in that the content of the second process in the seventh embodiment is replaced with the content of the electrode pattern forming method according to the ninth embodiment. There is no other difference between the embodiments, and thus a description of any common part will be omitted.

The electrode pattern forming methods according to the present disclosure are preferable for manufacturing of an electric component and a circuit board. The methods of manufacturing an electric component according to the present disclosure are preferable for manufacturing of, for example, a chip capacitor.

### Other Embodiments

The first area 31 is defined to be an area in which the first conductive portion 21 (solid portion) is to be formed, and the second area 32 is defined to be an area in which the second conductive portion 22 (line portion) is to be formed. However, the first area 31 only needs to correspond to at least part of the first conductive portion 21, and the second area 32 only needs to correspond to at least part of the second conductive portion 22. In other words, differences in the resolution and the number of iterations of recoating do not need to be provided between the entire area in which the first conductive portion 21 is to be formed and the entire area in which the second conductive portion 22 is to be formed. Differences in the resolution and the number of iterations of recoating may be provided between at least part of the area in which the first conductive portion 21 is to be formed and at least part of the area in which the second conductive portion 22 is to be formed.

What is claimed is:

1. A method of forming an electrode pattern including a first conductive portion and a second conductive portion connected with each other onto a work piece by an ink-jet process, said method comprising
defining a first area corresponding to at least part of the first conductive portion, and a second area corresponding to at least part of the second conductive portion on an identical surface of the work piece,
ejecting conductive ink droplets toward the first area and the second area to form the first conductive portion and the second conductive portion, and
differing a resolution of conductive ink droplets between the first area and the second area.

2. A method of forming an electrode pattern including a first conductive portion and a second conductive portion connected with each other onto a work piece by an ink-jet process, said method comprising
defining a first area corresponding to at least part of the first conductive portion and a second area corresponding to at least part of the second conductive portion on an identical surface of the work piece,
ejecting conductive ink droplets toward the first area and the second area to form the first conductive portion and the second conductive portion, and
differing a number of iterations of recoating with conductive ink droplets between the first area and the second area.

3. The method according to claim 1, wherein the second area has a resolution higher than a resolution of the first area when the first conductive portion is a solid portion of the electrode pattern and the second conductive portion is a line portion of the electrode pattern.

4. The method according to claim 2, wherein the number of iterations of recoating of the second area is larger than the number of iterations of recoating of the first area when the first conductive portion is a solid portion of the electrode pattern and the second conductive portion is a line portion of the electrode pattern.

5. The method according to claim 2, wherein the first area has a resolution higher than the resolution of the second area.

6. The method according to claim 4, wherein conductive ink droplets are ejected toward the first area after an iteration of recoating at which conductive ink droplets are ejected toward the second area.

7. The method according to claim 3, wherein
when a third area is defined to be in a vicinity of a boundary between the first area and the second area, conductive ink droplets are ejected toward the third area after an iteration of recoating at which conductive ink droplets are ejected toward the first area and the second area.

8. The method according to claim 7, wherein conductive ink droplets are ejected toward the third area at one of a resolution and the number of iterations of recoating that decreases at stages from the second area toward the first area.

9. The method according to claim 7, wherein the third area has a width defined to be smaller than a width of the second area.

10. A method of manufacturing an electric component, the method forming and firing a laminated structure including at least one work piece provided with an electrode pattern formed by the method according to claim 1.

11. A method of manufacturing an electric component in which a plurality of work pieces each provided with an electrode pattern formed by the method according to claim 1 are laminated in a predetermined lamination direction,
first conductive portions to be formed on the plurality of work pieces each overlapping with another electrode pattern in plan view along the lamination direction,
second conductive portions to be formed on the plurality of work pieces each not overlapping with another electrode pattern in plan view along the lamination direction, and
one of the resolution and the number of iterations of recoating of the first area being lower or smaller than a corresponding one of the resolution and the number of iterations of recoating of the second area.

12. A method of manufacturing an electric component in which a plurality of work pieces on each of which an electrode pattern is formed by the method according to claim 1 are laminated in a predetermined lamination direction,
first conductive portions to be formed on the plurality of work pieces being each a peripheral portion assumed to be relatively thicker,
second conductive portion to be formed on the plurality of work pieces being each an inner portion of the peripheral portion, and
one of the resolution and the number of iterations of recoating of the first area being lower or smaller than a corresponding one of the resolution and the number of iterations of recoating of the second area.

13. A method of manufacturing an electric component, the method forming and firing a laminated structure including at least one work piece provided with an electrode pattern formed by the method according to claim 2.

14. A method of manufacturing an electric component in which a plurality of work pieces each provided with an electrode pattern formed by the method according to claim 2 are laminated in a predetermined lamination direction,
first conductive portions to be formed on the plurality of work pieces each overlapping with another electrode pattern in plan view along the lamination direction,
second conductive portions to be formed on the plurality of work pieces each not overlapping with another electrode pattern in plan view along the lamination direction, and
one of the resolution and the number of iterations of recoating of the first area being lower or smaller than a corresponding one of the resolution and the number of iterations of recoating of the second area.

15. A method of manufacturing an electric component in which a plurality of work pieces on each of which an electrode pattern is formed by the method according to claim 2 are laminated in a predetermined lamination direction,
first conductive portions to be formed on the plurality of work pieces being each a peripheral portion assumed to be relatively thicker,
second conductive portion to be formed on the plurality of work pieces being each an inner portion of the peripheral portion, and
one of the resolution and the number of iterations of recoating of the first area being lower or smaller than a corresponding one of the resolution and the number of iterations of recoating of the second area.
